(19) United States
(12) Patent Application Publication
(10) Pub. No.: US 2006/0273384 A1
(43) Pub. Date: Dec. 7, 2006

(54) Structure for avalanche improvement of ultra high density trench MOSFET

(75) Inventor: Fwu-Iuan Hshieh, Saratoga, CA (US)

Correspondence Address: Bo-In Lin, 13445 Mandoli Drive, Los Altos Hills, CA, 94022, US

(73) Assignee: M-MOS Sdn. Bhd.

(21) Appl. No.: 11/236,007

(22) Filed: Sep. 26, 2005

Related U.S. Application Data
(63) Continuation-in-part of application No. 11/147,075, filed on Jun. 6, 2005.

(51) Int. Cl. H01L 29/78; H01L 21/336

(52) U.S. Cl. 257/330; 438/270; 438/589; 257/334

(57) ABSTRACT

A trenched metal oxide semiconductor field effect transistor (MOSFET) cell that includes a trenched gate surrounded by a source region encompassed in a body region above a drain region disposed on a bottom surface of a substrate. The MOSFET cell further includes a source-body contact trench opened with sidewalls substantially extend vertically relative to a top surface into the source and body regions and filled with contact metal plug. A body-resistance reduction region doped with body-doped is formed to surround the source-body contact trench to reduce a body-region resistance between the source-body contact metal and the trenched gate to improve an avalanche capability.

This patent application is a Continuation in Part (CIP) Application of a co-pending application Ser. No. 11/147,075 filed by a common Inventor of this Application on Jun. 6, 2005. The Disclosures made in that Application is hereby incorporated by reference.

### BACKGROUND OF THE INVENTION

1. Field of the Invention

This invention relates generally to the cell structure and fabrication process of power semiconductor devices. More particularly, this invention relates to a novel and improved cell structure and improved process for fabricating a trenched semiconductor power device with improved avalanche capability.

2. Description of the Prior Art

Conventional technologies of forming aluminum metal contact to the N+ source and P-well formed in the P-body regions in a semiconductor device is encountering a technical difficulty of poor metal coverage and unreliable electrical contact when the cell pitch is shrunken. The technical difficulty is especially pronounced when a metal oxide semiconductor field effect transistor (MOSFET) cell density is increased above 200 million cells per square inch (200 M/in²) with the cell pitch reduced to 1.8 um or to even a smaller dimension. The metal contact space to both N+ source and P-well in the P-body regions for cell density higher than 200M/in² is less than 1.0 um, resulting in poor metal step coverage and high contact resistance to both N+ and P-body region. The device performance is adversely affected by these poor contacts and the product reliability is also degraded.

Referring to FIG. 1 for a standard conventional MOSFET cell 10 formed in a semiconductor substrate 15 with a drain region of a first conductivity type, e.g., an N+ substrate, formed at a bottom surface. The trenched MOSFET cell is formed on top of an epitaxial layer 20 of a first conductivity type, e.g., N-epi-layer that having a lower dopant concentration than the substrate. A body region 25 of a second conductivity type, e.g., a P-body region 25, is formed in the epi-layer 20 and the body region 25 encompasses a source region 30 of the first conductivity type, e.g., N+ source region 30. Each MOSFET cell further includes a N+ doped polysilicon gate 35 disposed in a trench insulated from the surrounding epi-layer 20 with a gate oxide layer 40. The MOSFET cell is insulated from the top by an NSG and BPSG layer 45-1 and 45-2 with a source contact opening to allow a source contact metal layer 50 comprises titanium or Ti/TiN layer 50 to contact the source regions 30. For the purpose of reducing the ohmic resistance of the source contact 50, a P+ doped region, e.g., a Pwell region 55 is formed below the source contact 55 between the source regions 30 to improve the electrical contact. A single metal contact layer 60 overlaying on top to contact the N+ and P-well horizontally. The prior art MOSFET cell as shown in FIG. 1 encounters two fundamental issues due to the cell pitch shrinkage. One is the reduced contact area to both N+ source and P-body, resulting in high contact resistance. Another is poor metal step coverage due to high aspect ratio of contact height and open dimension.

In U.S. Pat. No. 6,638,826, Zeng et al. disclose a MOS power device as shown in FIG. 2 with a self-aligned trenched gate and source contacts formed with V-groove trench contact to dispose single layer of metal to electrically contact the source vertically. For the purpose of enhance the source contact, a P+ doped region is formed surrounding the V-groove trench. Even that the contact CD (Critical Dimension) can be shrunk without significantly increasing contact resistance, however, the single metal contact to the source region vertically has the drawback that it is difficult to further shrink the critical dimension due to the single metal contact structure. Particularly, the contact CD is limited by the problem of aluminum metal step coverage that often occurs when the depth to width ratio of the V-groove is increased as a result of further shrinking of the cell size. Moreover, because of the self-aligned contact without leaving enough space between the trench gate and the V-groove contact, the P+ may touch the channel region causing high threshold voltage Vth issue.

Another limitation of conventional MOSFET device that has a cell density higher than 200 million cells per square inch (200 M/in²) is the limited avalanche current due to the concerns of inadvertent triggering parasitic N+PN bipolar parasitically exists between the source disposed next to the P-body with the P-body further adjacent to the N-epitaxial layer. For DC-to-DC applications, even though it is important to increase the avalanche current, the conventional MOSFET devices as shown in FIGS. 1 and 2 are still limited by the requirement to avoid the turning on the parasitic bipolar without having metal step coverage and high Vth issues as result of cell density increase. Therefore, for the semiconductor power device such as the MOSFET, there are still difficulties to achieve the design goals of increasing the cell density and in the meantime, improving the avalanche capability.

Therefore, there is still a need in the art of the semiconductor device fabrication, particularly for trenched power MOSFET design and fabrication, to provide a novel transistor structure and fabrication process that would resolve these difficulties and design limitations.

### SUMMARY OF THE PRESENT INVENTION

It is therefore an object of the present invention to provide new and improved processes to form a more reliable source contact metal layer with smaller CD to allow for higher cell density and also for surrounding the source contact trench with doped region to reduce the body resistance such that the above-discussed technical difficulties of limited avalanche capability may be resolved.

Specifically, it is an object of the present invention to provide a new and improved cell configuration and fabrication process to form a source metal contact by opening a source-body contact trench by applying an oxide etch followed by a silicon etch. The source-body contact trench then filled with a metal plug to assure reliable source contact is established. The source-body contact trench is further surrounded with doped region to reduce the body resistance between the source-body contact trench and the trenched gate to avoid turning on the parasitic NPN bipolar with higher avalanche current. The new and improved MOSFET configurations can therefore overcome the problems and limitations encountered by the conventional semiconductor power devices.

Another aspect of the present invention is to further increase the avalanche capability by forming a buried region doped with a first conductivity type under the body regions to direct the avalanche current directly from the buried regions to the source-body contact. The drain-to-source resistance is reduced and the avalanche capability is further enhanced.

Briefly, in a preferred embodiment, the present invention discloses a trenched metal oxide semiconductor field effect transistor (MOSFET) cell that includes a trenched gate surrounded by a source region encompassed in a body region above a drain region disposed on a bottom surface of a substrate. The MOSFET cell further includes a source-body contact trench opened with sidewalls substantially perpendicular to a top surface into the source and body regions and filled with contact metal plug. A body-resistance reduction region doped with body-doped is formed to surround the source-body contact trench to reduce a body-region resistance between the source-body contact metal and the trenched gate to improve an avalanche capability. In a preferred embodiment, the contact metal plug further comprising a Ti/TiN barrier layer surrounding a tungsten core as a source-body contact metal. In another preferred embodiment, the MOSFET cell further includes an insulation layer covering a top surface over the MOSFET cell wherein the source body contact trench is opened through the insulation layer. And, the MOSFET cell further includes a thin resistance-reduction conductive layer disposed on a top surface covering the insulation layer and contacting the contact metal plug whereby the resistance-reduction conductive layer having a greater area than a top surface of the contact metal plug for reducing a source-body resistance. In another preferred embodiment, the contact metal plug filled in the source body contact trench comprising a substantially cylindrical shaped plug. In another preferred embodiment, the MOSFET cell further includes a thick front metal layer disposed on top of the resistance-reduction layer for providing a contact layer for a wire or wireless bonding package. In an alternate preferred embodiment, the source-body contact trench having stepwise sidewalls and said contact metal plug filled in said source-body contact trench comprising a substantially cup shaped plug having a wider top contact area. In a preferred embodiment, the MOSFET device further includes a doped buried region disposed below the body region for improving the avalanche capability and the drain to source resistance of the MOSFET device.

This invention further discloses a method for manufacturing a trenched metal oxide semiconductor field effect transistor (MOSFET) cell comprising a step of forming said MOSFET cell with a trenched gate surrounded by a source region encompassed in a body region above a drain region disposed on a bottom surface of a substrate. The method further includes a step of covering the MOSFET cell with an insulation layer and applying a contact mask for opening a source-body contact trench with sidewalls substantially perpendicular to a top surface of the insulation layer into the source and body regions. The method further includes a step of forming a body-resistance-reduction region by implanting a body-resistance-reduction-dopant in the body region immediately near the source-body contact trench whereby an avalanche capability of the MOSFET cell is enhanced. In a preferred embodiment, the step of implanting the body-resistance-reduction-dopant is a step of implanting a dopant of a same conductivity type as a body dopant doped in the body region. In a preferred embodiment, the step of forming the body-resistance-reduction region further includes a step of forming the body-resistance-reduction region surrounding a bottom portion of the source-body contact trench. In a preferred embodiment, the step of forming the body-resistance-reduction region further comprising a step of forming the body-resistance-reduction region immediately below a bottom of the source-body contact trench. In a preferred embodiment, the step of opening the source-body contact trench further comprising a step of opening the source-body contact trench with the sidewalls converging with a small tilted angle relative to a perpendicular direction to the top surface of the substrate. In a preferred embodiment, the method further includes a step of forming a buried region by implanting source-dopant ions below the body region for further enhancing the avalanche capability.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIG. 1 is a side cross-sectional view of a conventional MOSFET device.

FIG. 2 is a cross sectional view of a trenched MOSFET device with V-Groove trench contact disclosed by a patented disclosure.

FIG. 3 is a cross sectional view of a MOSFET device of this invention with an improved source-plug contact disposed in sloped source-body contact trenches and doped regions surrounding the trenched source-body contact to reduce the ohmic resistance Rp of the body region.

FIG. 4 is a cross sectional view of a MOSFET device of this invention with an improved source-plug contact disposed in perpendicular source-body contact trenches and doped regions surrounding the trenched source-body contact to reduce the ohmic resistance Rp of the body region.

FIG. 5 is a cross sectional view of a MOSFET device of this invention with an improved source-plug contact disposed in perpendicular source-body contact trenches and doped regions under the trenched source-body contact to reduce the ohmic resistance Rp of the body region.

FIG. 6 is a cross sectional view of a MOSFET device of this invention with an improved source-plug contact disposed in sloped source-body contact trenches and doped regions surrounding the trenched source-body contact to reduce the ohmic resistance Rp of the body region and the MOSFET device further includes a buried N+ regions under the body region.

FIG. 7 is a cross sectional view of a MOSFET device of this invention with an improved source-plug contact disposed in perpendicular source-body contact trenches and doped regions surrounding the trenched source-body contact to reduce the ohmic resistance Rp of the body region and the MOSFET device further includes a buried N+ regions under the body region.

FIG. 8 is a cross sectional view of a MOSFET device of this invention with an improved source-plug contact disposed in perpendicular source-body contact trenches and doped regions under the trenched source-body contact to reduce the ohmic resistance Rp of the body region and the MOSFET device further includes a buried N+ regions under the body region.

FIGS. 9A to 9J are a serial of side cross sectional views for showing the processing steps for fabricating a semiconductor trench as shown in FIGS. 3 and 6.

FIG. 9G′ is a side cross sectional view for illustrating a tilted angular ion implant process to form the P+ doped regions surrounding a source-body contact trench with perpendicular sidewalls.

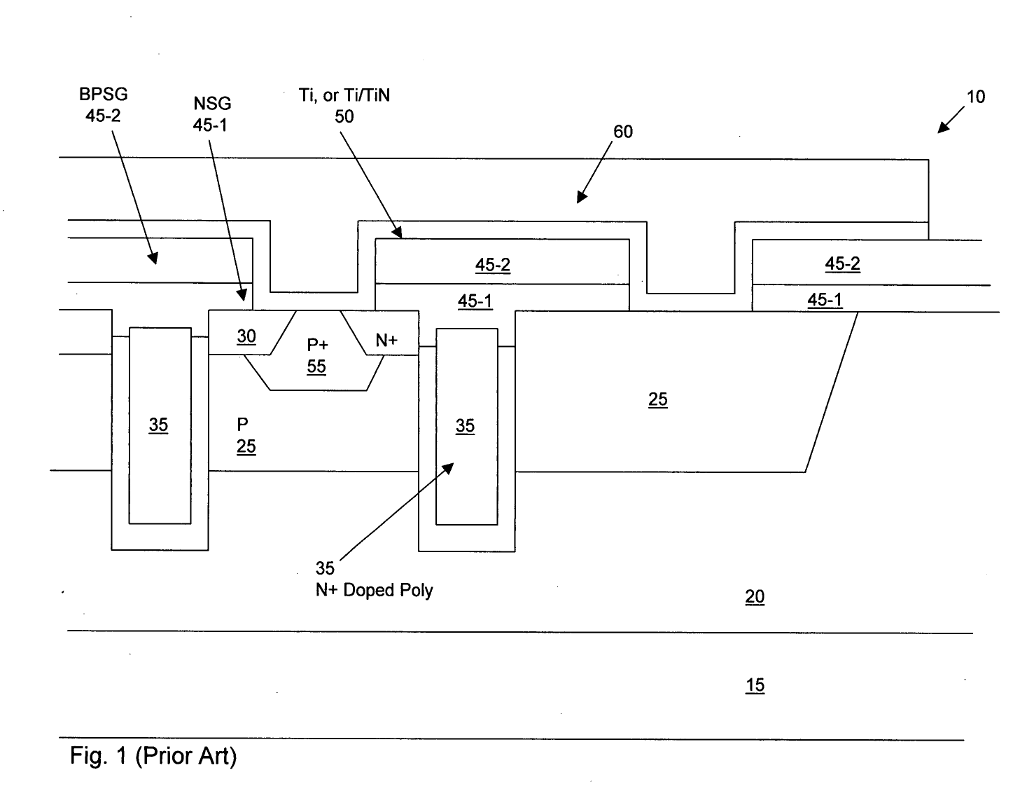

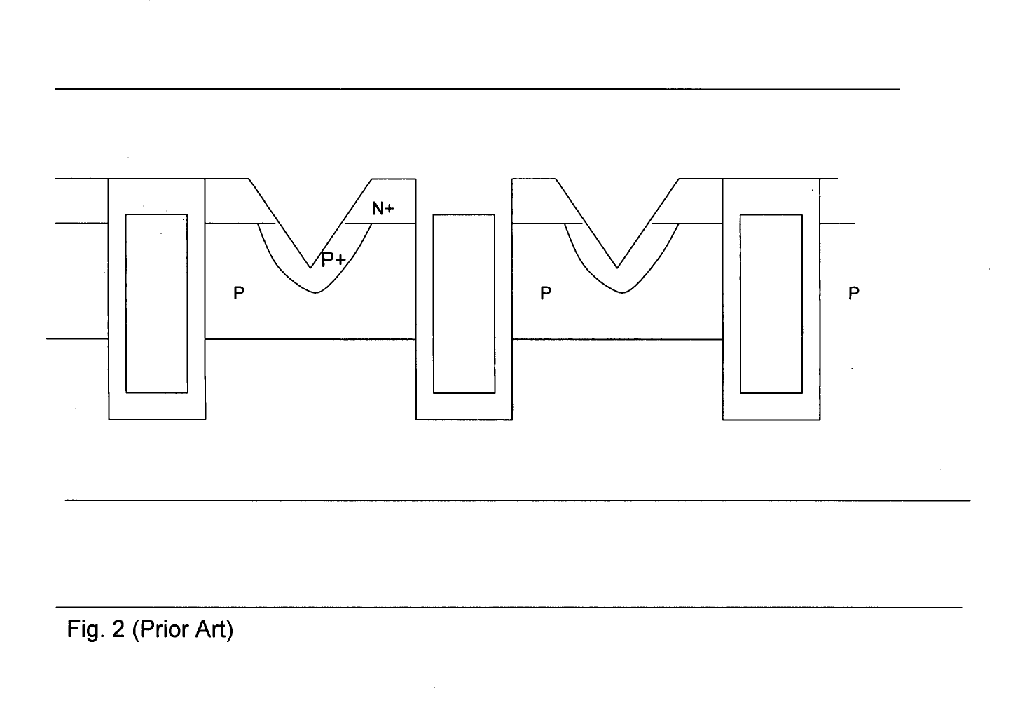

### DETAILED DESCRIPTION OF THE PREFERRED EMBODIMENT

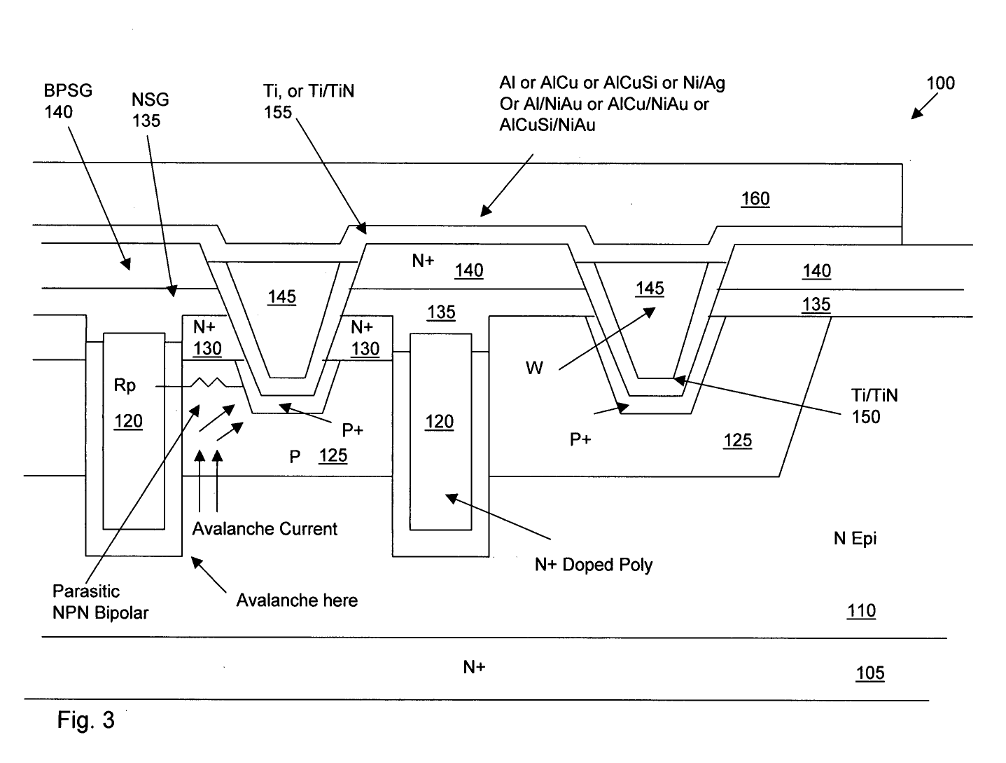

Please refer to FIG. 3 for a first preferred embodiment of this invention where a metal oxide semiconductor field effect transistor (MOSFET) device 100 is supported on a N+ substrate 105 formed with an N epitaxial layer 110. The MOSFET device 100 includes a trenched gate 120 disposed in a trench with a gate insulation layer 115 formed over the walls of the trench. A body region 125 that is doped with a dopant of second conductivity type, e.g., P-type dopant, extends between the trenched gates 120. The P-body regions 125 encompassing a source region 130 doped with the dopant of first conductivity, e.g., N+ dopant. The source regions 130 are formed near the top surface of the epitaxial layer surrounding the trenched gates 125. The top surface of the semiconductor substrate extending over the top of the trenched gate, the P body regions 125 and the source regions 130 are covered with a NSG and a BPSG protective layers 135 and 140 respectively.

For the purpose of improving the source contact to the source regions 130, a plurality of trenched source contact filled with a tungsten plug 145 surrounded by a barrier layer Ti/TiN 150. The contact trenches are opened through the NSG and BPSG protective layers 135 and 140 to contact the source regions 130 and the P-body 125. Then a conductive layer 155 is formed over the top surface to contact the trenched source contact 145 and 150. A top contact layer 160 is then formed on top of the source contact layer 155. The top contact layer 160 is formed with aluminum, aluminum-cooper, AlCuSi, or Ni/Ag, Al/NiAu, AlCu/NiAu or AlCuSi/NiAu as a wire-bonding layer. The conductive layer 155 sandwiched between the top wire-bonding layer 160 and the top of the trenched source-plug contact is formed to reduce the resistance by providing greater area of electrical contact.

Referring to FIG. 3 again, the source-body trenched contract 145 surrounded by the barrier layer 150 as shown are opened with a slope relative to the regular perpendicular direction for contacting a P+ doped region 128 surrounding the source-body trenched contact. The P+ doped region 128 is formed to enhance avalanche current before triggering parasitic N+PN bipolar, i.e., the N+ source 130 with a P-body 125 and the N-epitaxial layer 110. A high avalanche current is an important parameter for application in DC/DC conversion devices. A parasitic N+PN bipolar will be turned on when the avalanche current Iav*Rp is equal to 0.7 volts where Iav is the avalanche current and Rp is the resistance underneath the N+ source regions between the trenched gate 120 and the trenched source contact 145 as shown in FIG. 3. For the purpose of not triggering the parasitic bipolar N+PN, by reducing the resistance Rp with a P+ doped regions surrounding the trenched source-body contact 145 as implemented in this embodiment, a higher value of avalanche current Iav is achievable to obtain better performance in a DC/DC conversion device. As will be further described and discussed below of the processing steps in forming the MOSFET as shown, the sloped trenches allow the formation of heavily doped P+ doped regions 128 along both the trench sidewalls and the bottom through zero degree ion implantation of boron or BF-2. The heavily doped P+ regions 128 provide good ohmic contact between the Ti/TiN/W source body contact 145 and the P-body to reduce the parasitic resistance Rp underneath the N+ source regions 130. The embodiment enable an avalanche to occur near the bottom-corner of the trenched gate 120 and the avalanche current flows through the P-body 125 then collected by the Ti/TiN/W trenched source-body contact 145. The reduced body resistance Rp as discussed above enhances the avalanche current without triggering the turning on of a parasitic N+PN bipolar parasitically formed between the N+ source 130 with a P-body 125 and the N-epitaxial layer 110.

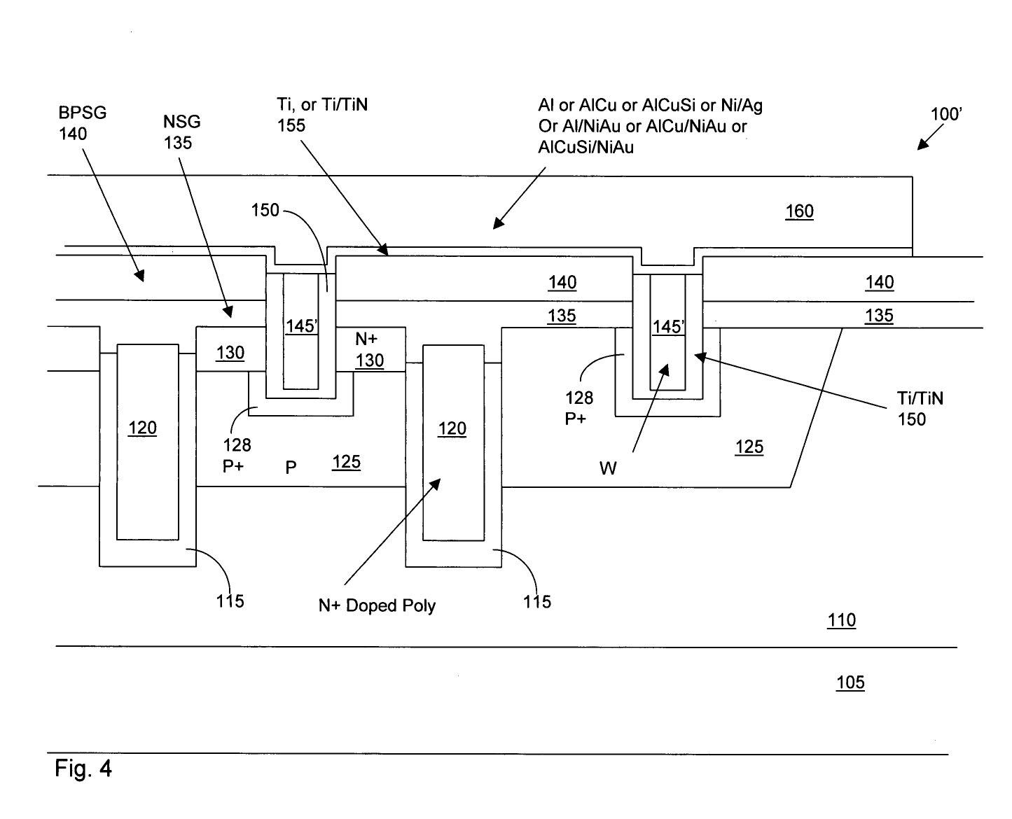

FIG. 4 shows another MOSFET device 100′ with similar device configuration as that shown in FIG. 3. The MOSFET device 100′ also has a source contact plug 145′ composed of tungsten surrounded by conductive barrier layer Ti/TiN 150′. The only difference is the shape of the trench for disposing the source contact plug 145′. Instead of a sloped sidewalls as shown in FIG. 3, the sidewalls are formed with a perpendicular sidewalls. As will be further discussed below about the processing steps, an angular ion implantation process is applied to form the high doped region 128 surrounding the trenched source-body contact 145′. The highly P+ doped regions 128 serves the same function as described for FIG. 3. With the P+ doped regions 128, a body resistance Rp is reduced to achieve a higher avalanche current Iav without inadvertently triggering the turning on of a parasitic N+PN bipolar that is parasitically formed between the N+ source 130 with a P-body 125 and the N-epitaxial layer 110.

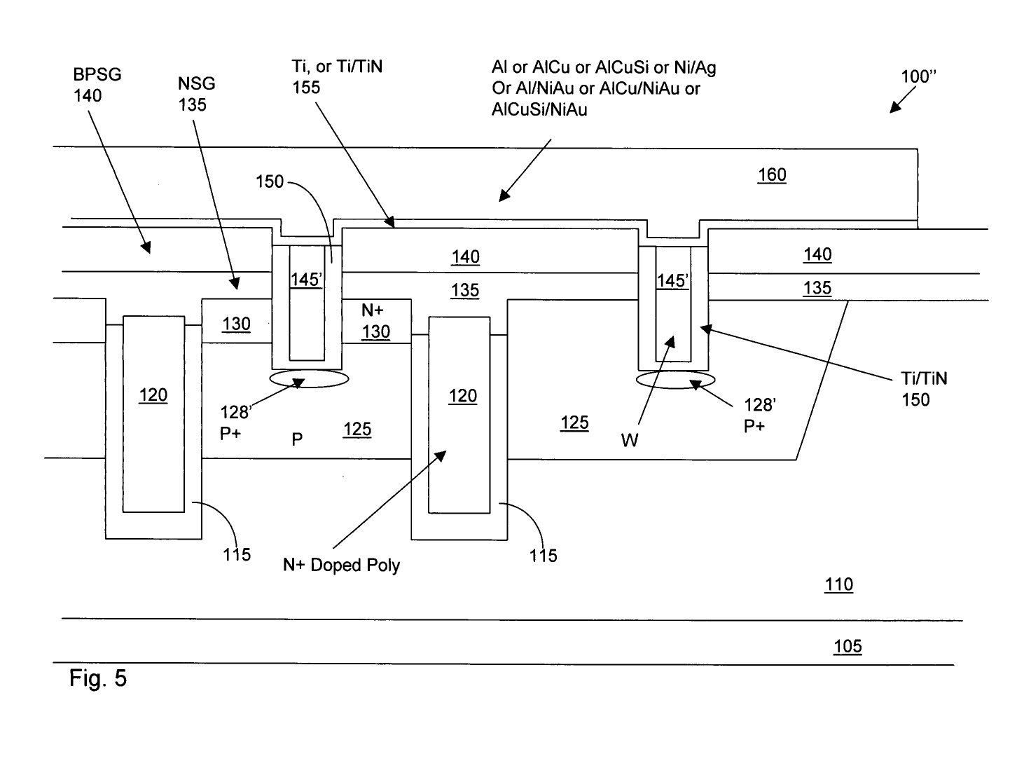

FIG. 5 shows another MOSFET device 100″ with similar device configuration as that shown in FIG. 4. The MOSFET device 100″ also has a source contact plug 145′ composed of tungsten surrounded by conductive barrier layer Ti/TiN 150′ just like the MOSFET shown in FIG. 4. Instead of a P+ doped region 128 that surrounds the trenched source-body contact 145′, a P+ doped region 128′ is formed underneath the trenched source-body contact 145′. As will be further discussed below about the processing steps, a zero-degree ion implantation process is applied to form the high doped region 128′ underneath the trenched source-body contact 145′. The highly P+ doped regions 128′ serves the same function as described for FIGS. 3 and 4. With the P+ doped regions 128′, a body resistance Rp is reduced to achieve a higher avalanche current Iav without inadvertently triggering the turning on of a parasitic N+PN bipolar that is parasitically formed between the N+ source 130 with a P-body 125 and the N-epitaxial layer 110.

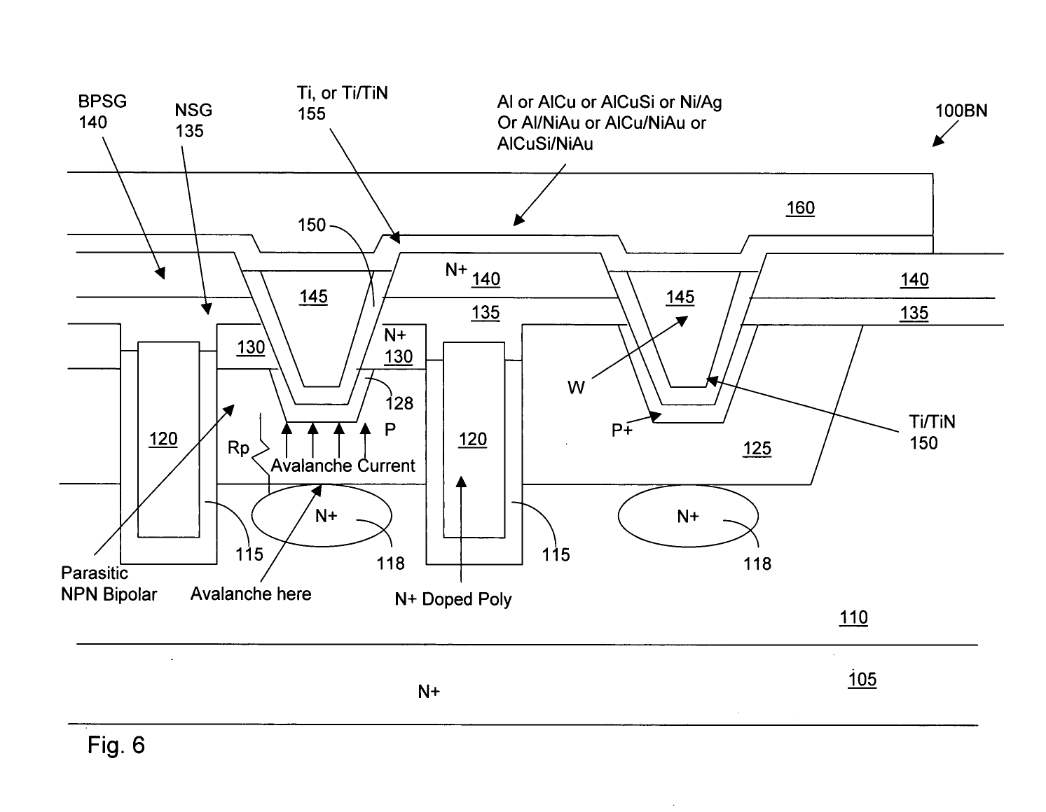

FIG. 6 shows another MOSFET device 100BN with similar device configuration as that MOSFET 100 shown in FIG. 3. The MOSFET device 100BN also has a source contact plug 145 composed of tungsten surrounded by conductive barrier layer Ti/TiN 150. The only difference between MOSFET 100 and MOSFET 100BN is a buried N+region 118 underneath the P-body regions 125 in the N-epitaxial layer 110. The buried N+ region 118 causes an avalanche to occur near the buried N+ regions 118 at the bottom of the P-body region 125 instead of the trench bottom corner of the trenched gate 120. The avalanche current as shown flows directly into the P-body regions 125 and collected by the Ti/TiN/W trenched body-source trenched contact 145 instead of flowing through the channel regions thus lowering the parasitic resistance. Furthermore, the drain to source resistance is reduced because the buried N+ region 118. The reduced Rds further reduces the spreading resistance between the drain and the channel region.

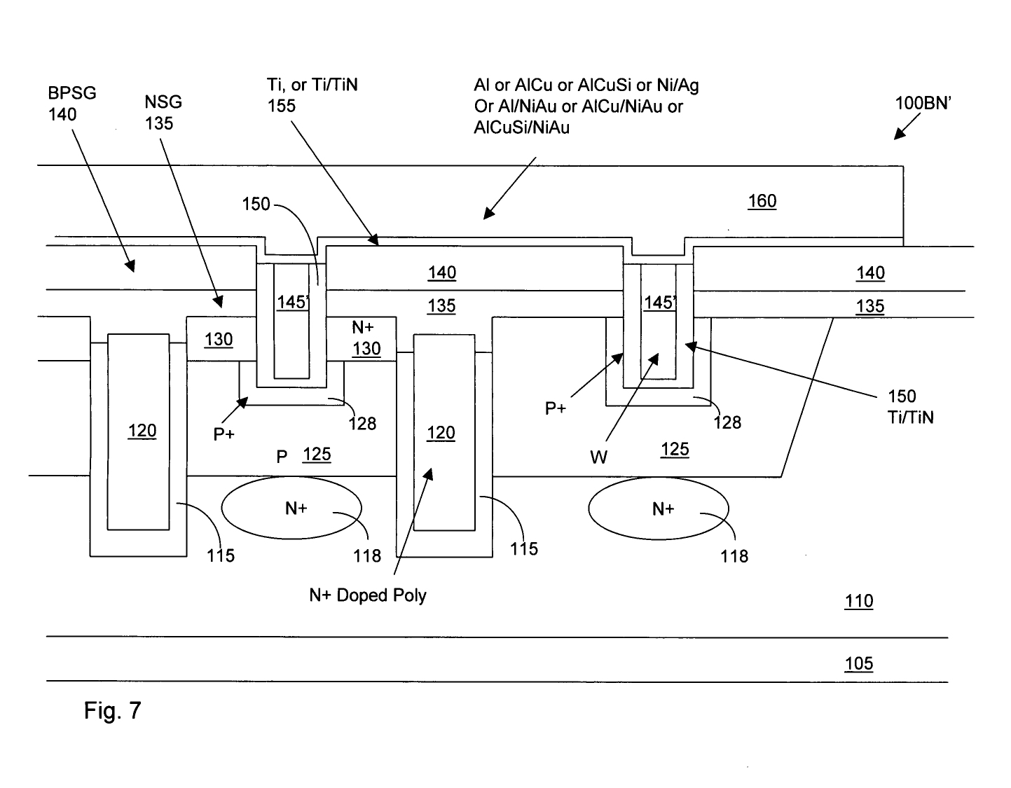

FIG. 7 shows another MOSFET device 100BN′ with similar device configuration as that MOSFET 100BN shown in FIG. 6. The only difference is the shape of the trench for disposing the source contact plug 145′. Instead of the sloped sidewalls as shown in FIG. 6, the sidewalls are formed as perpendicular sidewalls. Similar to the MOSFET 100′ shown in FIG. 4, an angular ion implantation process is applied to form the high doped region 128 surrounding the trenched source-body contact 145′. The highly P+ doped regions 128 serves the same function as described for FIG. 3. With the buried N+ doped regions underneath the P-body regions, the avalanche current flows directly into the P-body regions 125 and collected by the trenched body-source trenched contact 145 instead of flowing through the channel regions thus lowering the parasitic resistance. The drain to source resistance and the spreading resistance between the drain and the channel regions are also reduced.

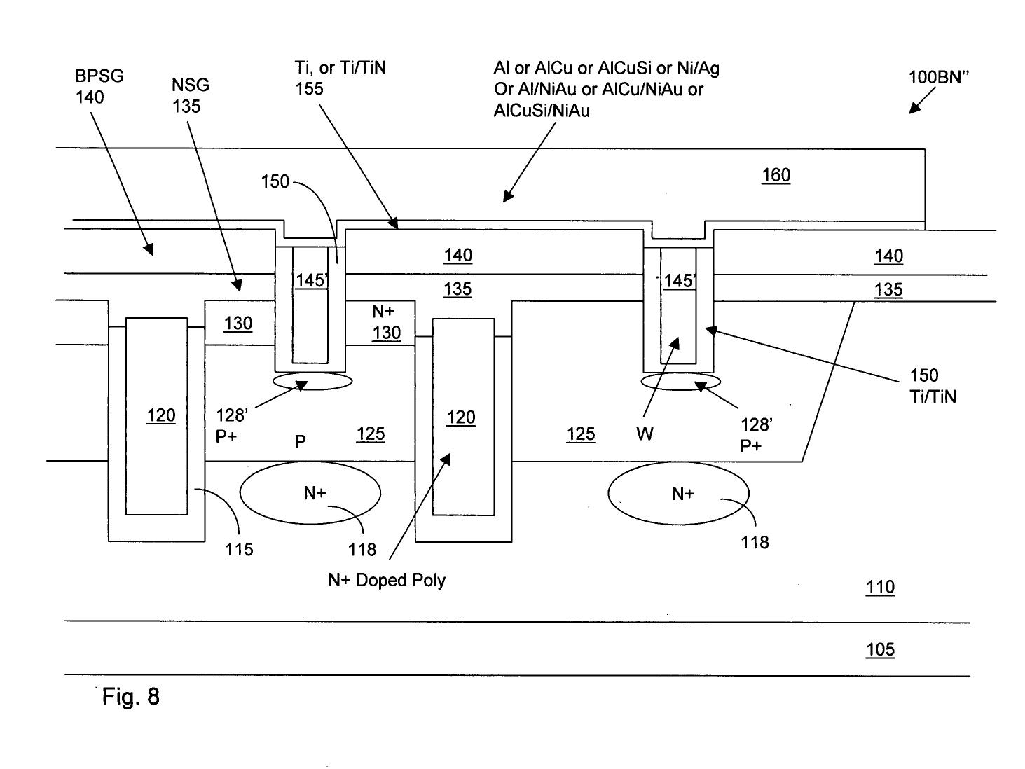

FIG. 8 shows another MOSFET device 100BN″ with similar device configuration as that MOSFET 100BN′ shown in FIG. 7. Instead of a P+ doped region 128 that surrounds the trenched source-body contact 145′, a P+ doped region 128′ is formed underneath the trenched source-body contact 145′. As will be further discussed below about the processing steps, a zero-degree ion implantation process is applied to form the high doped region 128′ underneath the trenched source-body contact 145′. With the buried N+ doped regions underneath the P-body regions, the avalanche current flows directly into the P-body regions 125 and collected by the trenched body-source trenched contact 145 instead of flowing through the channel regions thus lowering the parasitic resistance. The drain to source resistance and the spreading resistance between the drain and the channel regions are also reduced.

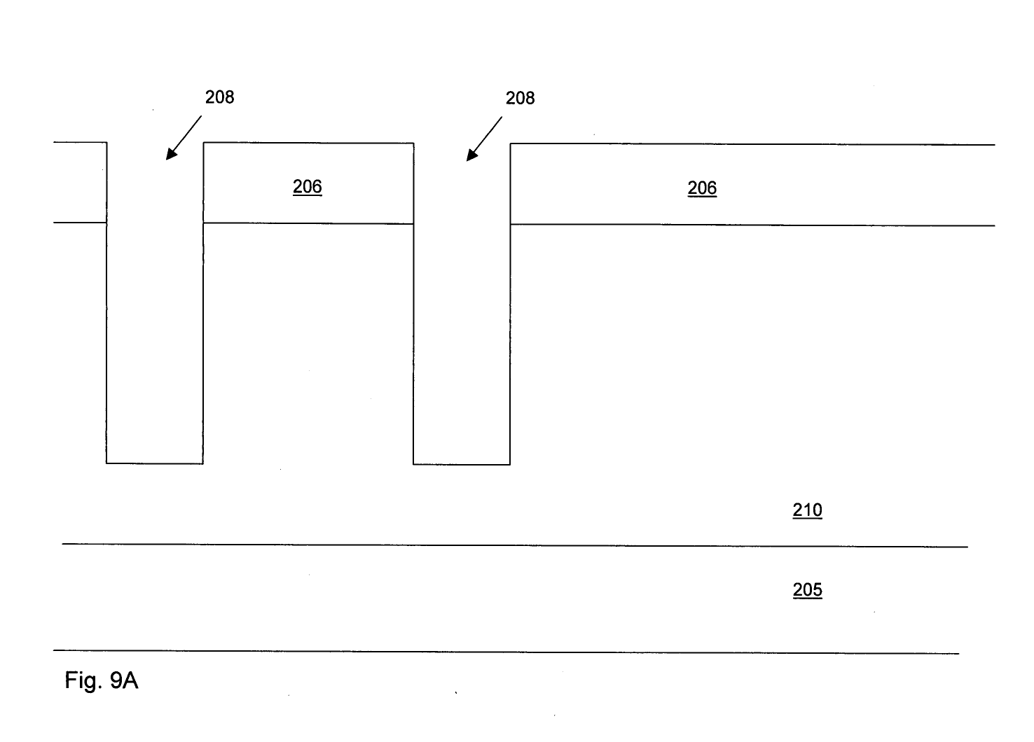

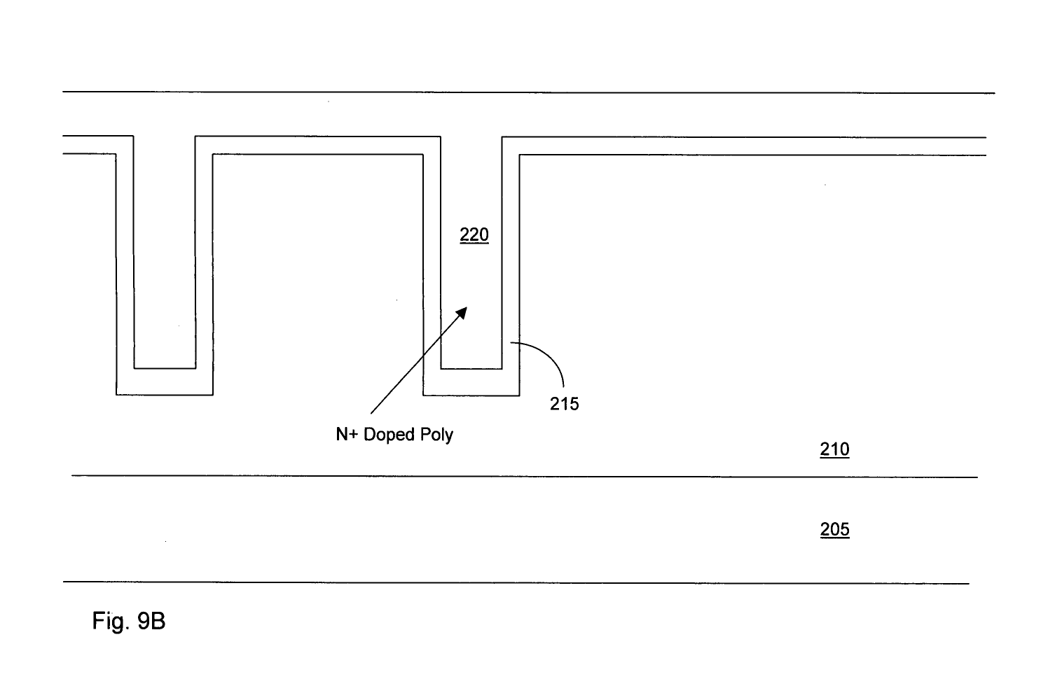

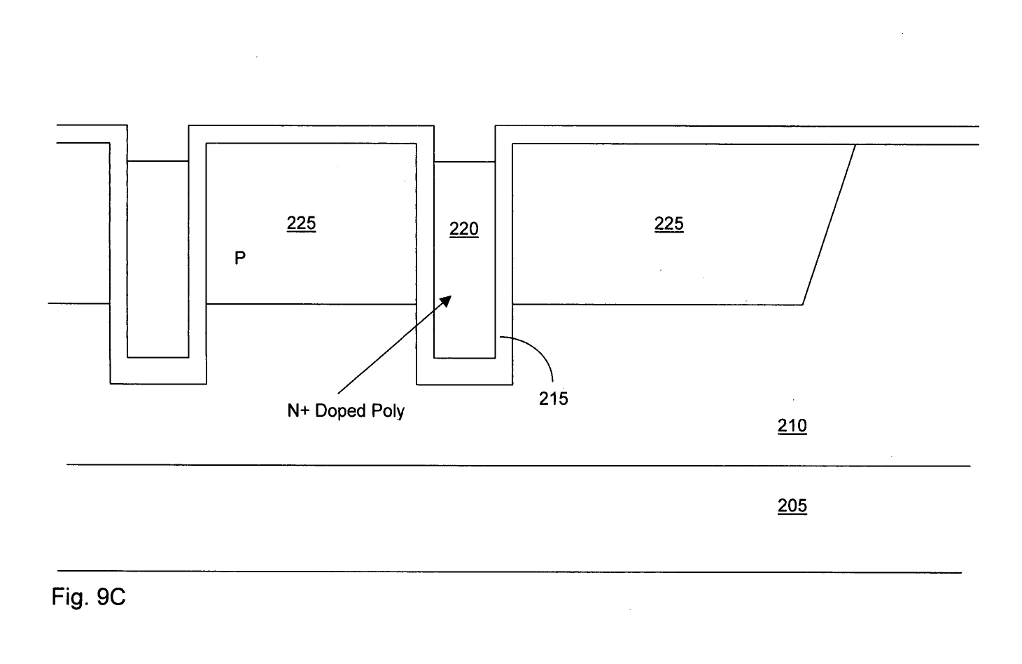

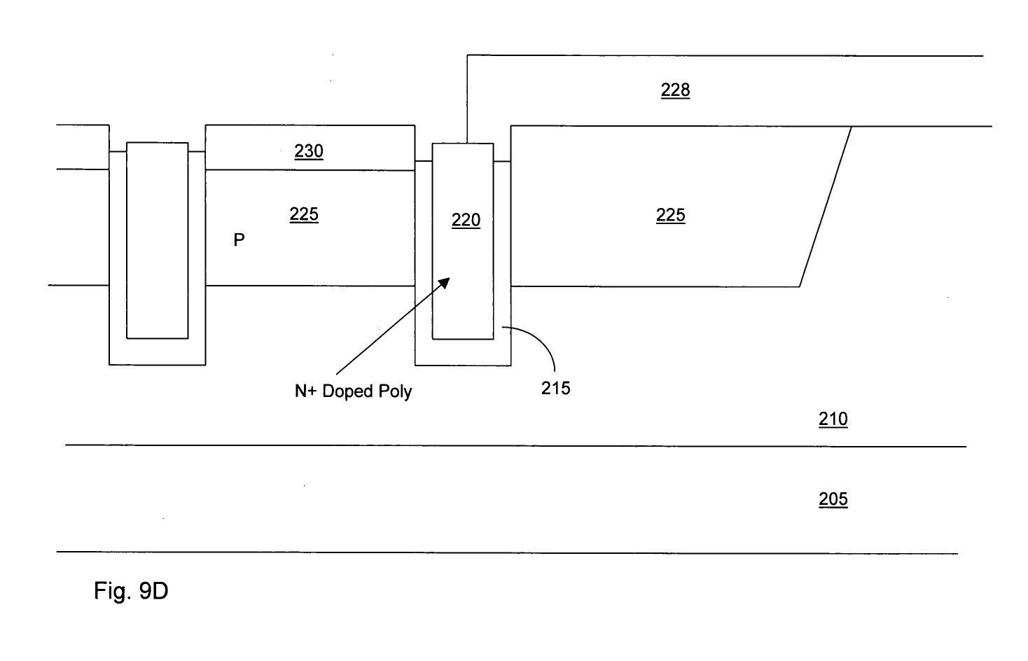

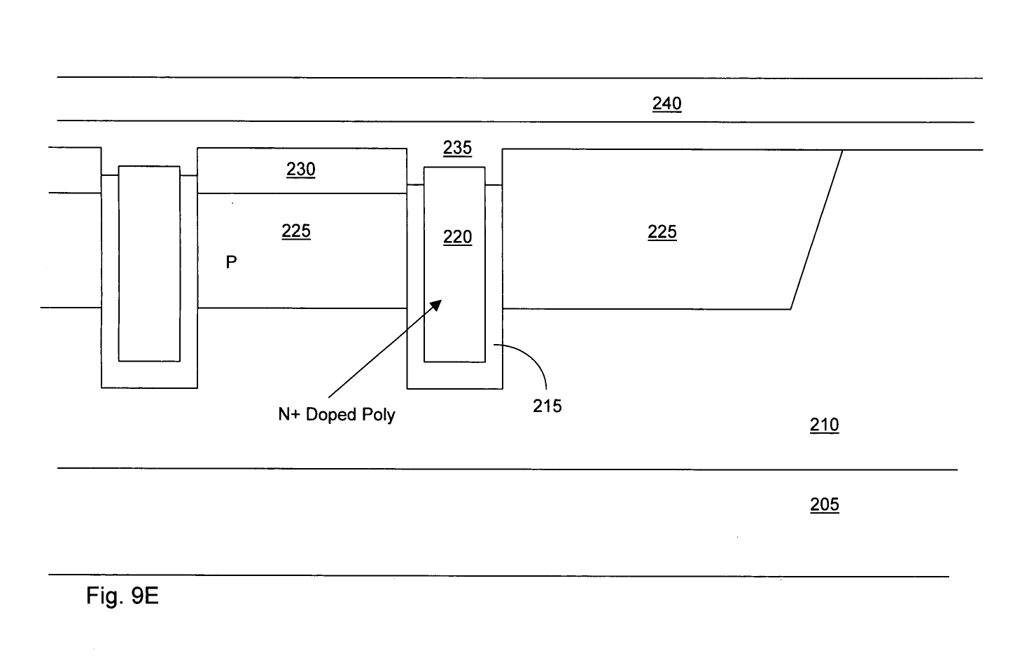

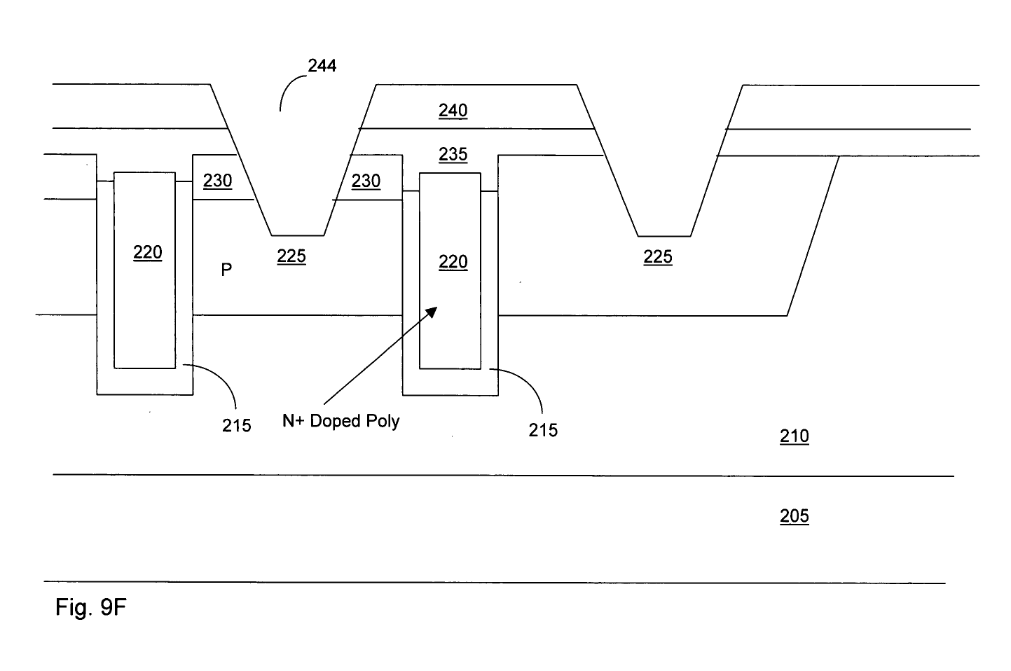

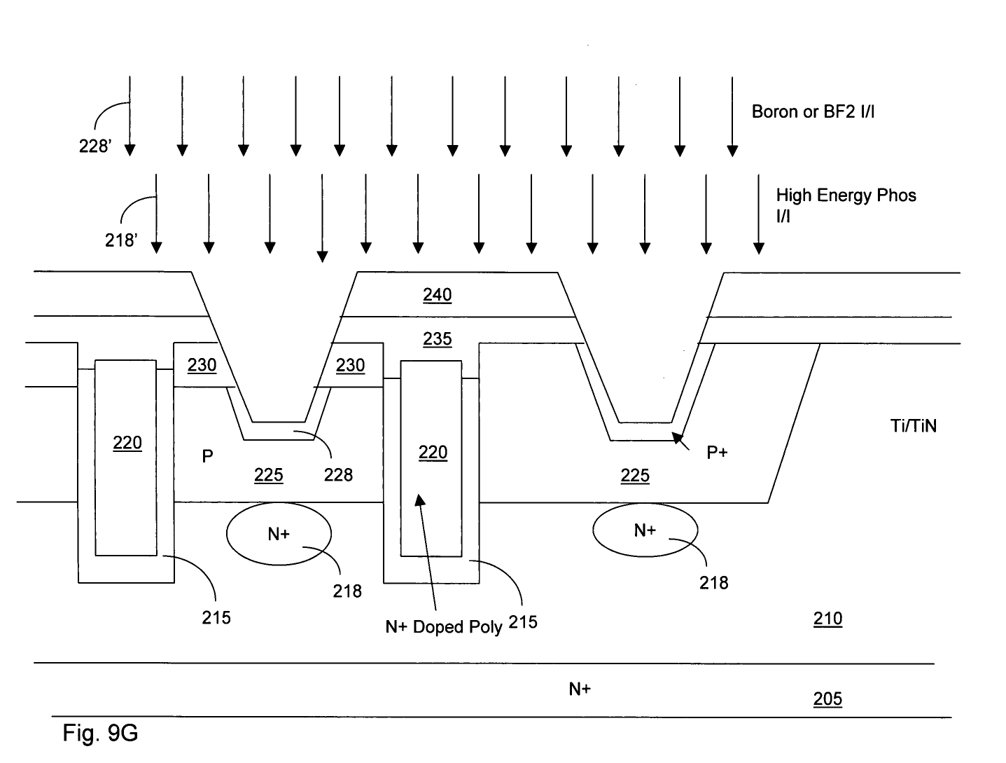

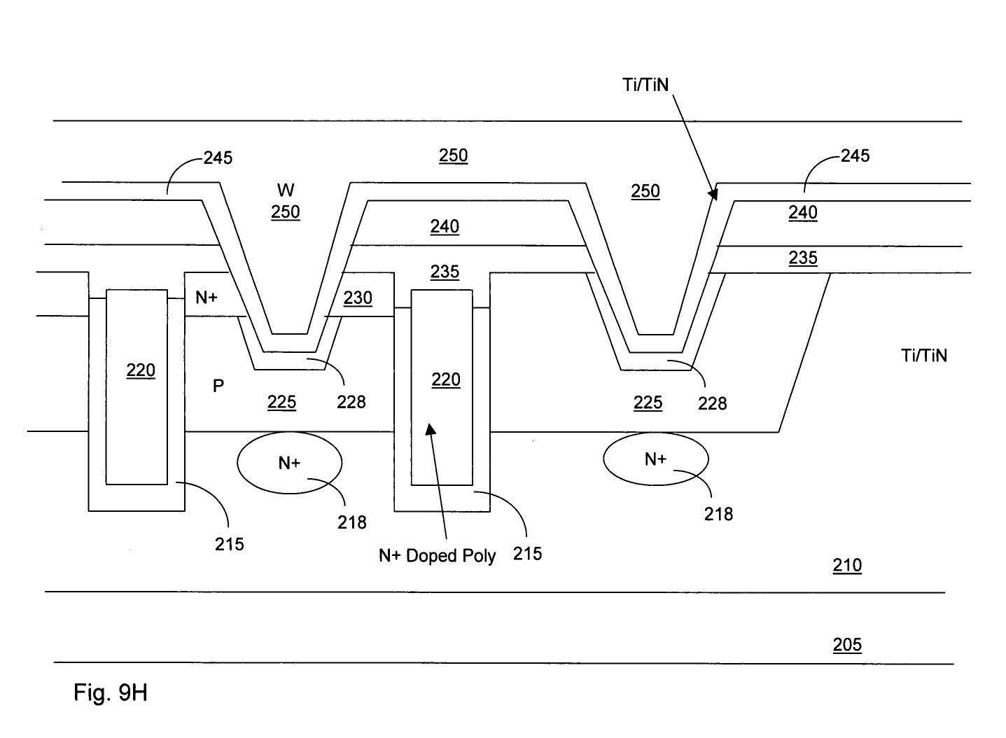

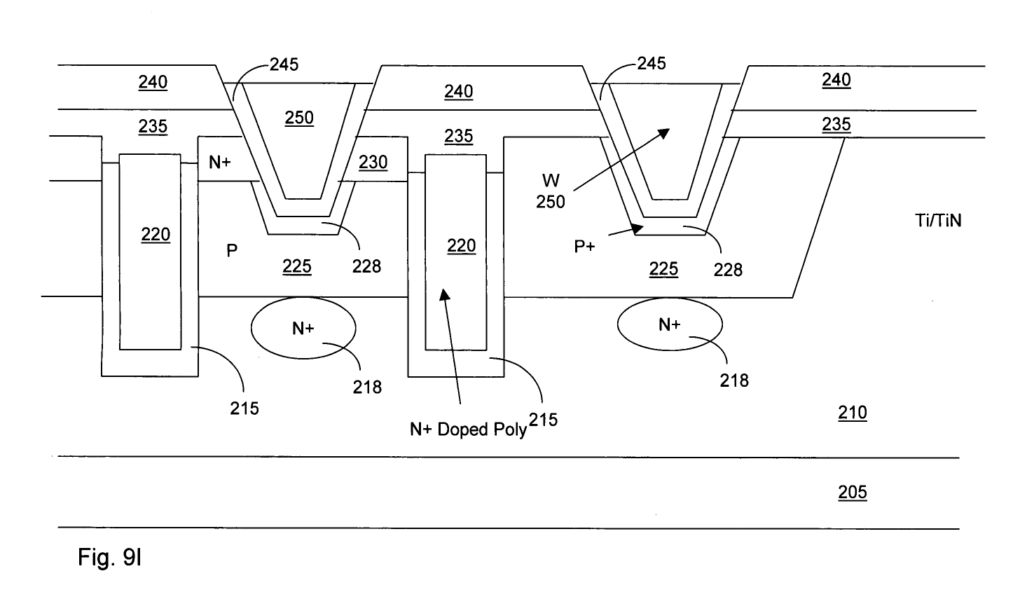

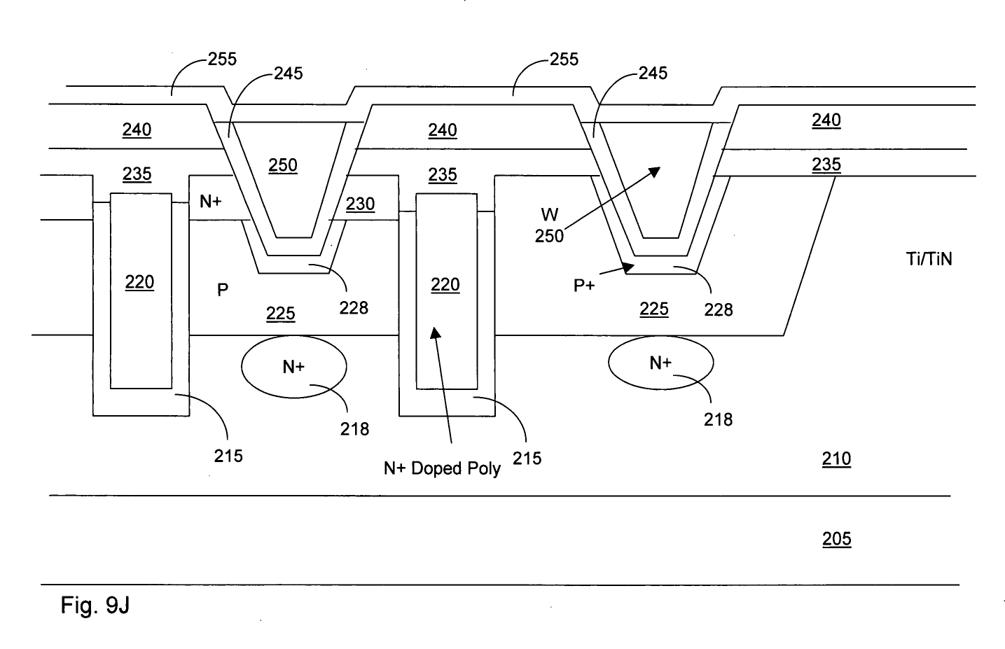

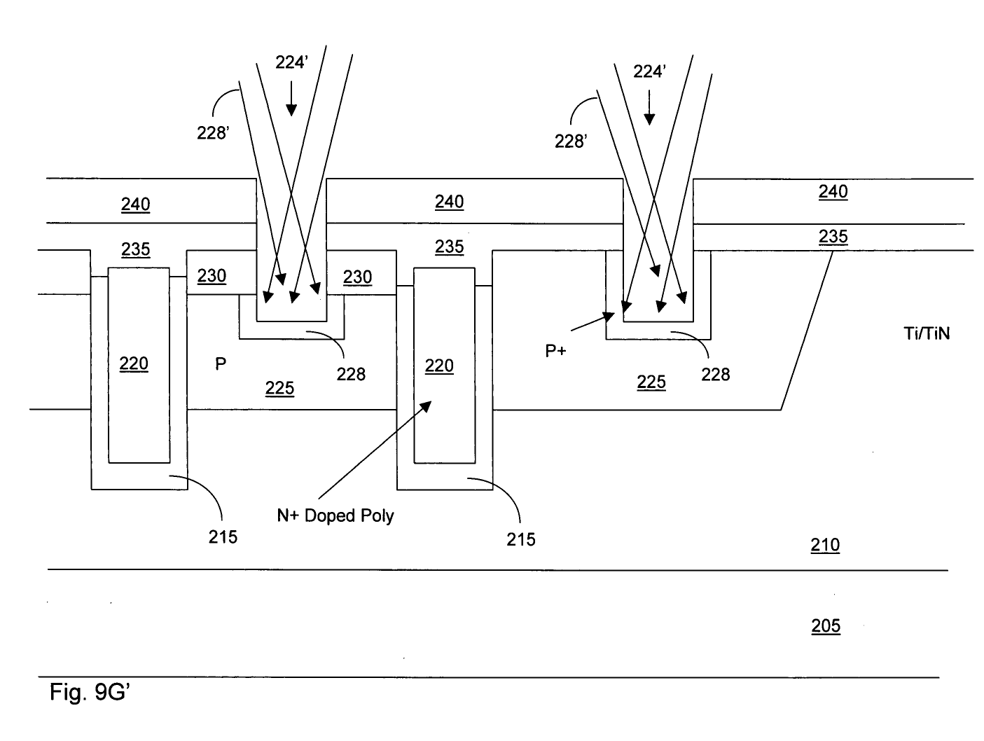

Referring to FIGS. 9A to 9J for a serial of side cross sectional views to illustrate the fabrication steps of a MOSFET device as that shown in FIG. 3. In FIG. 9A, a photoresist 206 is applied to open a plurality of trenches 208 in an epitaxial layer 210 supported on a substrate 205. In FIG. 9B, an oxidation process is performed to form an oxide layer 215 covering the trench walls. The trench is oxidized with a sacrificial oxide to remove the plasma damaged silicon layer during the process of opening the trench. Then a polysilicon layer 220 is deposited to fill the trench and covering the top surface and then doped with an N+ dopant. In FIG. 9C, the polysilicon layer 220 is etched back followed by a P-body implant with a P-type dopant. Then an elevated temperature is applied to diffuse the P-body 225 into the epitaxial layer 210. In FIG. 9D, a source mask 228 is applied followed by an source implant with a N-type dopant. Then an elevated temperature is applied to diffusion the source regions 230. In FIG. 9E, a non-doped oxide (NSG) layer 235 and a BPSG layer 240 are deposited on the top surface. In FIG. 9F, a contact mask 242 is applied to carry out a contact etch to open the contact opening 244 by applying an oxide etch through the BPSG and NSG layers followed by a silicon etch to open the contact openings 242 further deeper into the source regions 230 and the body regions 225. The MOSFET device thus includes a source-body contact trench 244 that has an oxide trench formed by first applying an oxide-etch through the oxide layers, e.g., the BPSG and NSG layers. The source-body contact trench 244 further includes a silicon trench formed by applying a silicon-etch following the oxide-etch. The oxide etch and silicon etch may be a dry oxide and silicon etch whereby a critical dimension (CD) of the source-body contact trench is better controlled. For the purpose of opening the source-body-contact trenches 244, different etching processes are available. The various slope and vertical contact trench profiles for the contact trenches 244 are achieved by using different gas ratios of C4F8 (or C3F6)/CO/O2/Ar plasma for dry oxide etch and CF4 (or HBr)/O2/Cl2 plasma for dry silicon etch.

In FIG. 9G, a boron or BF2 implant with P+ ions 228′ is first performed to form the P+ doped region 228 to surround the trenches 224. The implantation is carried out along a direction of zero degree relative to a perpendicular direction relative to the substrate top surface because the sloped sidewalls of the contact trenches 244. For the purpose of fabricating a MOSFET device 100BN as that shown in FIG. 6, a high energy ion implantation of phosphorus ions 218′ to form a N+ buried region 218 below the body regions 225 is carried out. In FIG. 9H, a Ti/TiN layer 245 is deposited onto the top layer followed by forming a tungsten layer 250 on the top surface that fill in the contact opening to function as a source and body contact plug. In FIG. 91, a tungsten etch is carried out to etch back the tungsten layer 250. In FIG. 9J, a Ti/TiN etch is carried out to etch back the Ti/TiN layer 245. A low resistance metal layer 255 is deposited over the top surface. The low resistance metal layer may be composed of Ti or Ti/TiN to assure good electric contact is established.

Referring further to FIG. 9G′ for different ion implantation processes to form the P+ doped regions 228 for MOSFET devices that has source-body contact trenches opened with sidewalls perpendicular to the top surface of the substrate. An ion implantation with boron or BF2 ions 228′ projected with a tilt angle relative to sidewalls of the source-body contact trenches 244′ to form the P+ doped regions 228 surrounding the source-body trenched contact 145′ as discussed above to reduced the body resistance Rp.

Although the present invention has been described in terms of the presently preferred embodiment, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

I claim:

1. A trenched metal oxide semiconductor field effect transistor (MOSFET) cell comprising a trenched gate surrounded by a source region encompassed in a body region above a drain region disposed on a bottom surface of a substrate, wherein said MOSFET cell further comprising:
a source-body contact trench opened with sidewalls extended substantially vertical relative to a top surface into said source and body regions and filled with contact metal plug; and
a body-resistance-reduction region doped with a body-resistance-reduction-dopant disposed in said body region immediately near said source-body contact trench whereby an avalanche capability of said MOSFET cell is enhanced.

2. The MOSFET cell of claim 1 wherein:
said body-resistance-reduction-dopant is a dopant of a same conductivity type as a body dopant doped in said body region.

3. The MOSFET cell of claim 1 wherein:
said body-resistance-reduction region further surrounding of said source-body contact trench.

4. The MOSFET cell of claim 1 wherein:
said body-resistance-reduction region further disposed immediately below a bottom of said source-body contact trench.

5. The MOSFET cell of claim 1 wherein:
said sidewalls of said source-body contact trench converging with a small tilted angle relative to a perpendicular direction to said top surface of said substrate.

6. The MOSFET cell of claim 1 further comprising:
a buried region doped with a source-dopant disposed below said body region whereby said avalanche capability is further enhanced.

7. The MOSFET cell of claim 1 wherein:
the contact metal plug further comprising a Ti/TiN barrier layer surrounding a tungsten core as a source-body contact metal.

8. The MOSFET cell of claim 1 further comprising:
an insulation layer covering a top surface over said MOSFET cell wherein said source body contact trench is opened through said insulation layer; and
a thin resistance-reduction conductive layer disposed on a top surface covering said insulation layer and contacting said contact metal plug whereby said resistance-reduction conductive layer having a greater area than a top surface of said contact metal plug for reducing a source-body resistance.

9. The MOSFET cell of claim 1 wherein:
said contact metal plug filled in said source body contact trench comprising a substantially cylindrical shaped plug.

10. The MOSFET cell of claim 1 wherein:
the source body contact trench further comprising an oxide trench formed by an oxide-etch through an oxide layer covering a top surface said MOSFET device.

11. The MOSFET cell of claim 1 wherein:
the source body contact trench further comprising a trench formed by etching with different gas ratios of C4F8/CO/O2/Ar plasma for an oxide etch and CF4/O2/Cl2 plasma for a dry silicon etch for extending said sidewalls of said source-body contract trench into said substrate with a small tilt angle relative to a perpendicular direction to a top surface of said substrate.

12. The MOSFET cell of claim 1 wherein:
the source body contact trench further comprising a trench formed by etching with different gas ratios of C3F6/CO/O2/Ar plasma for an oxide etch and CF4/O2/Cl2 plasma for a dry silicon etch for extending said sidewalls of said source-body contract trench into said substrate with a small tilt angle relative to a perpendicular direction to a top surface of said substrate.

13. The MOSFET cell of claim 1 wherein:
the source body contact trench further comprising a trench formed by etching with different gas ratios of C4F8/CO/O2/Ar plasma for an oxide etch and HBr/O2/Cl2 plasma for a dry silicon etch for extending said sidewalls of said source-body contract trench into said substrate with a small tilt angle relative to a perpendicular direction to a top surface of said substrate.

14. The MOSFET cell of claim 1 wherein:
the source body contact trench further comprising a trench formed by etching with different gas ratios of C3F6/CO/O2/Ar plasma for an oxide etch and HBr/O2/Cl2 plasma for a dry silicon etch for extending said sidewalls of said source-body contract trench into said substrate with a small tilt angle relative to a perpendicular direction to a top surface of said substrate.

15. The MOSFET cell of claim 1 wherein:
the source body contact trench further comprising a trench opened by a dry oxide and silicon etch whereby a critical dimension (CD) of said source-body contact trench is better controlled.

16. The MOSFET cell of claim 1 wherein:
the contact metal plug further contacts said source region on trench sidewalls of said source body contact trench and contact metal plug contacts said body region through a bottom surface of said source body contact trench.

17. The MOSFET cell of claim 1 wherein:
said MOSFET cell further comprising a N-channel MOSFET cell.

18. The MOSFET cell of claim 1 wherein:
said MOSFET cell further comprising a P-channel MOSFET cell.

19. The MOSFET cell of claim 1 wherein:
said body-resistance-reduction region further surrounding said source-body contact trench extending over volumes in said body surrounding sidewalls and bottom portions of said source-body contact trench.

20. A method for manufacturing a trenched metal oxide semiconductor field effect transistor (MOSFET) cell comprising a step of forming said MOSFET cell with a trenched gate surrounded by a source region encompassed in a body region above a drain region disposed on a bottom surface of a substrate, the method further comprising:
covering said MOSFET cell with an insulation layer and applying a contact mask for opening a source-body contact trench with sidewalls substantially perpendicular to a top surface of said insulation layer into said source and body regions; and
forming a body-resistance-reduction region by implanting a body-resistance-reduction-dopant in said body region immediately near said source-body contact trench whereby an avalanche capability of said MOSFET cell is enhanced.

21. The method of claim 20 wherein:
said step of implanting said body-resistance-reduction-dopant is a step of implanting a dopant of a same conductivity type as a body dopant doped in said body region.

22. The method of claim 20 wherein:
said step of forming said body-resistance-reduction region further comprising a step of forming said body-resistance-reduction region surrounding said source-body contact trench.

23. The method of claim 20 wherein:
said step of forming said body-resistance-reduction region further comprising a step of forming said body-resistance-reduction region immediately below a bottom of said source-body contact trench.

24. The method of claim 20 wherein:
said step of opening said source-body contact trench further comprising a step of opening said source-body contact trench with said sidewalls converging with a small tilted angle relative to a perpendicular direction to said top surface of said substrate.

25. The MOSFET cell of claim 20 further comprising:
forming a buried region by implanting source-dopant ions below said body region for further enhancing said avalanche capability.

26. The method of claim 20 further comprising:
filling said source-body contact trench with contact metal plug.

27. The method of claim 20 wherein:
said step of forming said source body contact trench further comprising a carrying out an oxide etch with different gas ratios of C4F8/CO/O2/Ar plasma followed by carrying out a dry silicon etch with CF4/O2/Cl2 plasma for extending said sidewalls of said source-body contract trench into said substrate with a small tilt angle relative to a perpendicular direction to a top surface of said substrate.

28. The method of claim 20 wherein:
said step of forming said source body contact trench further comprising a carrying out an oxide etch with different gas ratios of C3F6/CO/O2/Ar plasma followed by carrying out a dry silicon etch with CF4/O2/Cl2 plasma for extending said sidewalls of said source-body contract trench into said substrate with a small tilt angle relative to a perpendicular direction to a top surface of said substrate.

29. The method of claim 20 wherein:
said step of forming said source body contact trench further comprising a carrying out an oxide etch with different gas ratios of C4F8/CO/O2/Ar plasma followed by carrying out a dry silicon etch with HBr/O2/Cl2 plasma for extending said sidewalls of said source-body contract trench into said substrate with a small tilt angle relative to a perpendicular direction to a top surface of said substrate.

30. The method of claim 20 wherein:
said step of forming said source body contact trench further comprising a carrying out an oxide etch with different gas ratios of C3F6/CO/O2/Ar plasma followed by carrying out a dry silicon etch with HBr/O₂/Cl2 plasma for extending said sidewalls of said source-body contract trench into said substrate with a small tilt angle relative to a perpendicular direction to a top surface of said substrate.

31. The method of claim 20 wherein:
said step of forming said body-resistance-reduction region further comprising a step of forming said body-resistance-reduction region surrounding both sidewalls and bottom portions of said source-body contact trench.
